(19) United States
(12) Patent Application Publication
(10) Pub. No.: US 2024/0234384 A1
(43) Pub. Date: Jul. 11, 2024

(54) METHOD AND DEVICE FOR TRANSFERRING ELECTRONIC CHIP

(71) Applicant: SAMSUNG ELECTRONICS CO., LTD., Suwon-si (KR)

(72) Inventors: Kyungwook HWANG, Suwon-si (KR); Youngtek OH, Suwon-si (KR); Dongkyun KIM, Suwon-si (KR); Dongho KIM, Suwon-si (KR); Joonyong PARK, Suwon-si (KR); Sanghoon SONG, Suwon-si (KR); Minchul YU, Suwon-si (KR); Junsik HWANG, Suwon-si (KR)

(73) Assignee: SAMSUNG ELECTRONICS CO., LTD., Suwon-si (KR)

(21) Appl. No.: 18/402,416

(22) Filed: Jan. 2, 2024

(30) Foreign Application Priority Data
Jan. 11, 2023 (KR) 10-2023-0004288
May 31, 2023 (KR) 10-2023-0070458

(51) Int. Cl. H01L 25/075

(52) U.S. Cl. CPC H01L 25/0753

(57) ABSTRACT

A method of transferring electronic chips includes attaching, to a relay substrate, the electronic chips arranged on a base substrate, separating the electronic chips from the base substrate, wetting a target substrate using a solvent, transferring, to the target substrate, the electronic chips that are attached to the relay substrate, pressing the relay substrate in a thickness direction of the target substrate, and drying the target substrate.

### CROSS-REFERENCE TO RELATED APPLICATIONS

This application is based on and claims priority under 35 U.S.C. § 119 to Korean Patent Application No. 10-2023-0004288, filed on Jan. 11, 2023 and to Korean Patent Application No. 10-2023-0070458, filed on May 31, 2023, in the Korean Intellectual Property Office, the disclosures of each of which being incorporated by reference herein in their entireties.

### BACKGROUND

Apparatuses, devices, and methods consistent with example embodiments relate to a method and device for transferring an electronic chip.

Since light emitting diodes (LEDs) are eco-friendly and have low power consumption, the industrial demand for such devices has increased. Also, the LEDs are used for a lighting device, a liquid crystal display (LCD) backlight, as pixels of a display device, etc. Recently, a micro-LED display device using a micro-LED chip as a pixel has been developed. In manufacturing a display device including a micro-LED chip, a laser lift off or a pick and place method is used to transfer micro LEDs. However, this method has reduced productivity as the size of the micro-LEDs decreases and the size of the display device increases.

### SUMMARY

It is an aspect to provide a method and device for transferring an electronic chip.

According to an aspect of one or more embodiments, there is provided a method of transferring a plurality of electronic chips, the method comprising attaching, to a relay substrate, the plurality of electronic chips arranged on a base substrate; separating the plurality of electronic chips from the base substrate; wetting a target substrate using a solvent; transferring, to the target substrate, the plurality of electronic chips that are attached to the relay substrate; pressing the relay substrate in a thickness direction of the target substrate; and drying the target substrate.

According to another aspect of one or more embodiments, there is provided a transfer device comprising a target substrate having a plurality of grooves; and a plurality of electronic chips transferred to the plurality of grooves by attaching, to a relay substrate, the plurality of electronic chips arranged on a base substrate, separating the plurality of electronic chips from the base substrate, wetting the target substrate using a solvent, transferring, to the target substrate, the plurality of electronic chips that are attached to the relay substrate, pressing the relay substrate in a thickness direction of the target substrate; and drying the target substrate.

### BRIEF DESCRIPTION OF THE DRAWINGS

Various embodiments will be more clearly understood from the following detailed description taken in conjunction with the accompanying drawings, in which:

FIG. 1 is a flowchart schematically illustrating a method of transferring an electronic chip according to an embodiment;

FIGS. 2A and 2B are diagrams illustrating a base substrate, a base region, and a second electronic chip according to an embodiment;

FIGS. 3A and 3B are diagrams illustrating a target substrate, a second region, and a first electronic chip according to an embodiment;

FIGS. 4A to 4G are diagrams illustrating a method of transferring an electronic chip according to an embodiment;

FIG. 5 is a cross-sectional view illustrating a plurality of grooves according to an embodiment;

FIG. 6 is a diagram schematically illustrating a structure of an electronic chip according to an embodiment;

FIG. 7 is a perspective view illustrating a method of aligning a plurality of electronic chips using a fluid self-assembly method, according to an embodiment;

FIGS. 8 and 9 are cross-sectional views of a display device including a transfer device according to an embodiment;

FIG. 10 is a block diagram of an electronic apparatus including a transfer device according to an embodiment;

FIG. 11 illustrates an example showing an electronic apparatus according to an embodiment applied to a mobile device;

FIG. 12 illustrates an example showing a display device according to an embodiment applied to a vehicle;

FIG. 13 illustrates an example showing a display device according to an embodiment applied to augmented reality glasses or virtual reality glasses;

FIG. 14 illustrates an example showing a display device according to an embodiment applied to a large signage; and

FIG. 15 illustrates an example showing a display device according to an embodiment applied to a wearable display.

### DETAILED DESCRIPTION

Hereinafter, various embodiments will be described in detail with reference to the accompanying drawings. In the following drawings, the same reference numerals refer to the same components, and the size of each component in the drawings may be exaggerated for clarity and convenience of description. Meanwhile, the various embodiments described below are merely illustrative, and various modifications are possible from these embodiments.

Hereinafter, the term “upper portion” or “on” may also include “to be present on the top, bottom, left or right portion on a non-contact basis” as well as “to be present just on the top, bottom, left or right portion in directly contact with”. Singular expressions include plural expressions unless the context clearly means otherwise. In addition, when a part “contains” a component, this language means that the part may contain other components, rather than excluding other components, unless otherwise stated.

The specific implementations described in the various embodiments are examples and are not intended to limit the technical scope in any manner. For the sake of simplicity of the specification, descriptions of conventional electronic configurations, control systems, software, and other functional aspects of the above systems may be omitted. In addition, the connection or connection members of lines between the components shown in the drawings exemplarily represent functional connection and/or physical or circuit connections, and may be replaceable or represented as various additional functional connections, physical connections, or circuit connections in an actual device.

The use of the term “the” and similar indicative terms may correspond to both singular and plural. Unless there is clear order or contrary description of the steps constituting the method, these steps may be performed in the appropriate order, and are not necessarily limited to the order described.

Further, the terms “unit”, “module” or the like mean a unit that processes at least one function or operation, which may be implemented in hardware or software or implemented in a combination of hardware and software.

The terms “first”, “second”, etc. may be used to describe various components, but the components should not be limited by terms. Terms are used only for the purpose of distinguishing one component from another.

The connection or connection members of lines between the components shown in the drawings exemplarily represent functional connection and/or physical or circuit connections, and may be replaceable or represented as various additional functional connections, physical connections, or circuit connections in an actual device.

The use of all examples or illustrative terms is simply to describe technical ideas in detail, and the scope is not limited due to these examples or illustrative terms unless the scope is limited by the claims.

According to an aspect of the present disclosure, a method of transferring a plurality of electronic chips may include attaching, to a relay substrate, the plurality of electronic chips arranged on a base substrate, separating the plurality of electronic chips attached to the relay substrate from the base substrate, wetting a target substrate using a solvent, transferring, to the target substrate, the plurality of electronic chips attached to the relay substrate, pressing the relay substrate in a thickness direction of the target substrate, and drying the target substrate.

In some embodiments, the transferring of the plurality of electronic chips to the target substrate may not include a predetermined adhesive.

In some embodiments, the relay substrate may be reused.

In some embodiments, the wetting may include applying a solvent to a plurality of grooves provided in the target substrate.

In some embodiments, the solvent may include at least one of H₂O, ethanol, acetone, and alcohol.

In some embodiments, the solvent may be a solvent that does not chemically react with the plurality of electronic chips.

In some embodiments, the method may further include removing first electronic chips in a number less than a reference number from a second region in the target substrate, the target substrate including a first region in which the reference number of the first electronic chips are arranged and the second region in which the first electronic chips in the number less than the reference number are arranged, and transferring the reference number of the second electronic chips to the second region.

In some embodiments, the transferring may further include separating the reference number of the second electronic chips from a base region provided on the base substrate on which the reference number of the second electronic chips are arranged.

In some embodiments, in the transferring, the plurality of second electronic chips may be transferred to the target substrate by a pick and place.

In some embodiments, the removing of the plurality of first electronic chips may separate all of the first electronic chips included in the second region.

In some embodiments, the transferring of the plurality of second electronic chips to the plurality of grooves arranged on the target substrate may transfer all the second electronic chips to the plurality of grooves provided in the target region.

In some embodiments, one side surface of each of the electronic chips may be parallel to a surface of the target substrate.

In some embodiments, one side surface of each of the plurality of grooves may be arranged to be inclined at a predetermined angle in a thickness direction of a surface of the target substrate.

In some embodiments, the predetermined angle may be 80° to 90°.

In some embodiments, the transferring may perform transferring such that the second electronic chips are arranged in the same manner as the first electronic chips.

In some embodiments, the transferring may perform transferring such that electrodes included in the second electronic chips face the outside of the target substrate.

In some embodiments, a plurality of grooves for accommodating each of the first electronic chips and the second electronic chips may be formed in the target substrate.

In some embodiments, the target substrate may include driving elements for a display device.

In some embodiments, a region in which the reference number of first electronic chips are arranged may correspond to a first sub-pixel for the display device, and a region in which the reference number of second electronic chips are arranged may correspond to a second sub-pixel for the display device.

According to another aspect of the present disclosure, a transfer device may include a target substrate having a plurality of grooves; and a plurality first electronic chips transferred to the plurality of grooves according to the method described above.

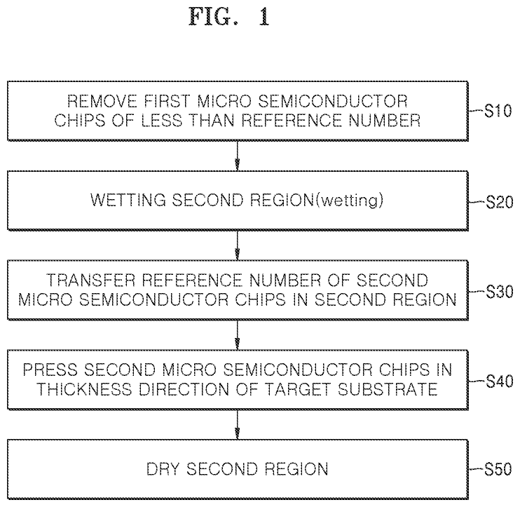

FIG. 1 is a flowchart schematically illustrating a method of transferring a plurality of electronic chips according to an embodiment.

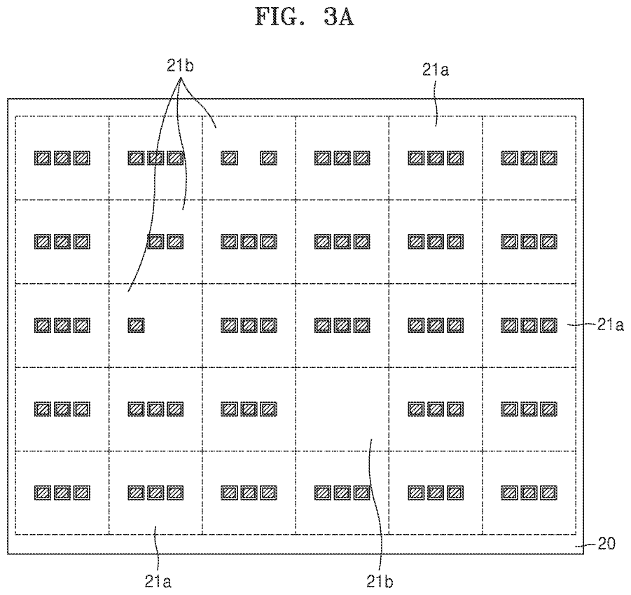

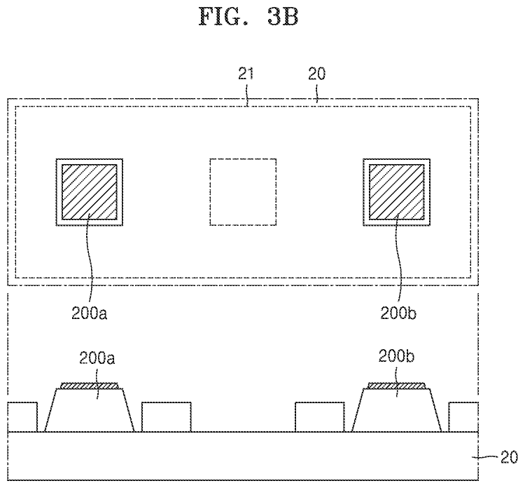

Referring to FIG. 1, a method of transferring a plurality of second electronic chips according to an embodiment includes transferring the plurality of second electronic chips to a target substrate 20 (of FIGS. 3A and 3B, for example). The transferring a plurality of electronic chips is different from transferring individual electronic chips one by one, and may be defined as transferring two or more, ten or more, 50 or more, and 100 or more electronic chips by one process. That is, transferring a plurality of electronic chips may be defined as transferring two or more, ten or more, 50 or more, and 100 or more electronic chips at one time. The method of transferring the plurality of second electronic chips may include removing first micro semiconductor chips of less than a reference number S10, wetting a second region S20, transferring the reference number of second micro semiconductor chips in the second regions S30, pressing the second micro semiconductor chips in a thickness direction of a target substrate S40 and drying the second region S50.

The plurality of second electronic chips may be mass-transferred in large quantities to the target substrate 20 by a pick-and-place method.

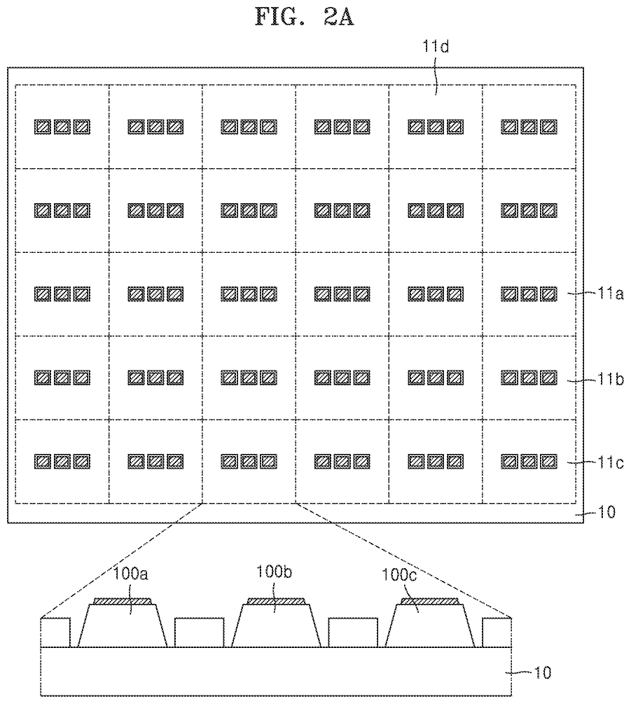

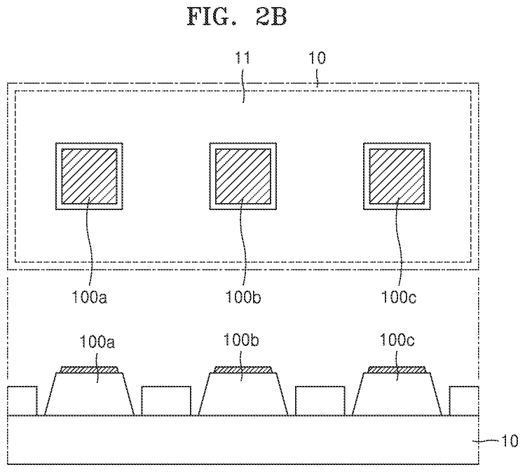

FIGS. 2A and 2B are diagrams illustrating a base substrate, a base region, and a second electronic chip according to an embodiment.

Referring to FIG. 2A, according to an embodiment, a plurality of base regions 11a, 11b, 11e, 11d, . . . may be provided on the base substrate 10, and a plurality of electronic chips 100a, 100b, 100c, . . . may be arranged in each of the plurality of regions.

Referring to FIG. 2B, a plan view and a cross-sectional view of one base region 11 and three second electronic chips 100a, 100b, and 100c provided in the base region 11 according to an embodiment are illustrated.

Each of the plurality of second electronic chips 100a, 100b, and 100c according to an embodiment may have a size of a micrometer unit or a nanometer unit. For example, each of the second electronic chips 100a, 100b, and 100c may have a size of 1,000 μm or less, for example, 500 μm or less, 200 μm or less, or 100 μm or less, according to various embodiments.

For example, each of the second electronic chips 100a, 100b, and 100c may be a micro light emitting device. However, the type of each of the second electronic chips 100a, 100b, and 100c is not limited thereto, and in some embodiments, any device including a material capable of growing on a substrate, for example, a material including a Group IV material, a Group III-V material, or sapphire, may be applied in various ways. As an example of a Group IV material, silicon may be used. As an example of the Group III-V material, indium phosphide (InP) or gallium arsenic (GaAs) may be used.

Each of the second electronic chips 100a, 100b, and 100c may include at least one of a light emitting device, a laser, and a detector. The detector may be an infrared sensor. For example, the detector may be a Short-Wave Infrared (SWIR) sensor or a Long-Wave Infrared (LWIR) sensor. However, the embodiments are not limited thereto.

FIGS. 3A and 3B are diagrams illustrating a target substrate, a first region or a second region, and a first electronic chip according to an embodiment.

Referring to FIG. 3A, a plurality of first regions 21a or second regions 21b may be provided on a target substrate 20. In each of the plurality of first regions 21a, a plurality of electronic chips 100a, 100b, 100c, . . . may be arranged. However, in some of the plurality of second regions 21b, a number of the electronic chips that may be arranged may be 0 to 2.

Referring to FIG. 3B, a plan view and a cross-sectional view of one second region 21 and two first electronic chips 200a and 200b provided in the second region 21 according to an embodiment are illustrated. For example, in the one second region illustrated in FIG. 3B, there is no electronic chip in a position between the two first electronic chips 200a and 200b. In some second regions of the plurality of second regions provided in the target substrate 20, a number of the electronic chips that may be arranged may be 0 to 2.

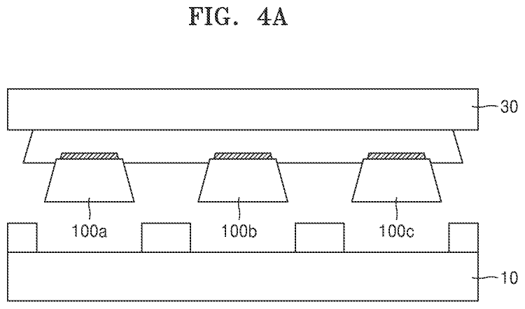

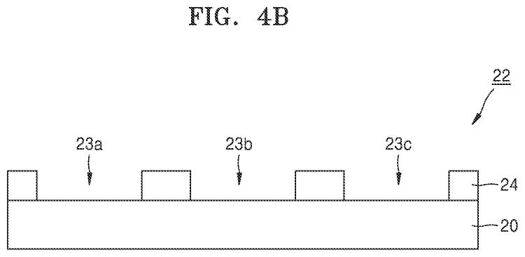

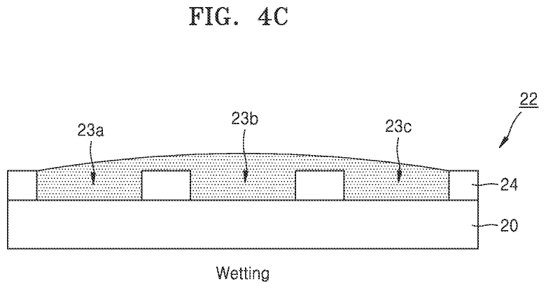

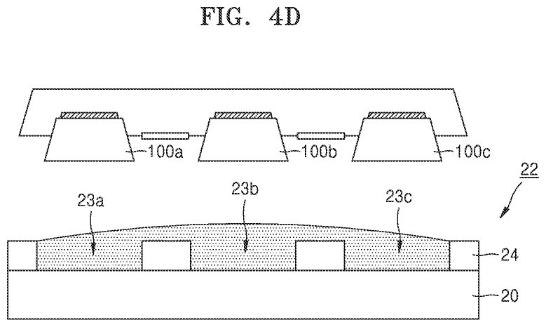

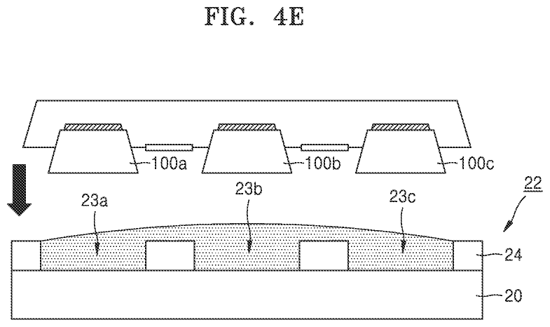

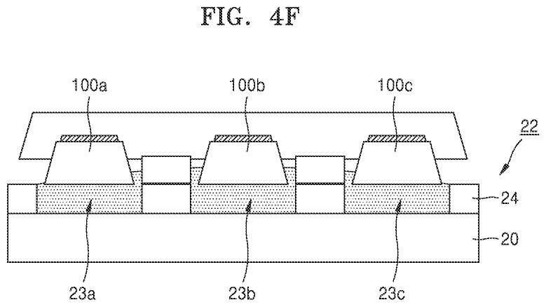

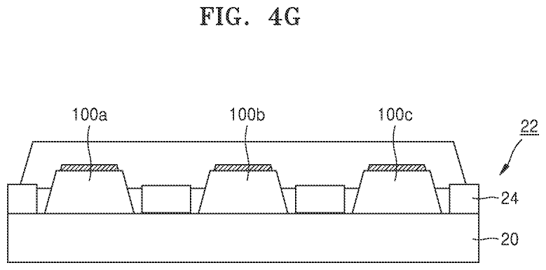

FIGS. 4A to 4G are diagrams illustrating a method of transferring an electronic chip according to an embodiment.

Referring to FIG. 4A, a base substrate 10 is provided. The plurality of second electronic chips 100a, 100b, and 100c may be separated from the base region 11 (of FIG. 2B) provided on the base substrate 10 by using an adhesive stamp 30.

Referring to FIG. 4B, the target region 22 provided in the target substrate 20 may include a plurality of grooves 23a, 23b, and 23c. The plurality of grooves may be arranged to be spaced apart from each other. The target region 22 may correspond to a pixel on which a plurality of first electronic chips separated from the base substrate are transferred to a region from which the second region is removed after removing, in units of pixels, the second region having a plurality of electronic chips of 0 or 2 or less from a predetermined second region arranged on the target substrate 20.

The plurality of grooves 23a, 23b, and 23c may be spaces for arranging the plurality of second electronic chips 100a, 100b, and 100c therein. Target molds 24 for defining the plurality of grooves may be arranged in the target region 22. The target molds 24 may be arranged between the plurality of grooves.

Referring to FIG. 4C, a solution is transferred to the target substrate 20 of the target region 22 in which the plurality of grooves 23a, 23b, and 23c are arranged, thereby wetting the target region 22. The solution may be predetermined. The predetermined solution may include a material that is easily absorbed by a material such as a substrate and has rapid evaporation. For example, the solution may be a solvent and the solvent may include at least one of H₂O, ethanol, acetone, and alcohol, but embodiments are not limited thereto, and in some embodiments, the solution may further include a predetermined solvent having a low viscosity.

Referring to FIG. 4D, the plurality of second electronic chips 100a, 100b, and 100c separated from the base substrate 10 may be transferred to the plurality of grooves 23a, 23b, and 23c provided in the target region 22 and spaced apart from each other. The plurality of second electronic chips and the plurality of grooves spaced apart from each other are as described above.

Referring to FIG. 4E, the plurality of second electronic chips 100a, 100b, 100c transferred to the plurality of grooves 23a, 23b, and 23c provided in the target region 22 may be pressed in the thickness direction of the target substrate 20. The thickness direction may be a direction orthogonal to the planar surface of the target substrate 20. By applying pressure to the plurality of second electronic chips, an adsorption force between the surface of the target substrate 20 and the plurality of second electronic chips 100a, 100b, and 100c may increase. The adsorption force may be, for example, a capacitive force, but embodiments are not limited thereto.

Referring to FIGS. 4F and 4G, the bottom surfaces of the plurality of grooves 23a, 23b, and 23c provided in the target region 22 are dried to greatly increase the adhesive force between the plurality of second electronic chips 100a, 100b, and 100c and the target substrate 20. In the process of drying the solvent, a van der Waals force may occur between one side surface of the second electronic chip and the surface of the target substrate 20, and the adhesive force of both materials based on the van der Waals force may be greater than the force applied between the adhesive stamp 30 and the plurality of second electronic chips 100a, 100b, and 100c. After the second electronic chip is completely adsorbed on the target substrate, the adhesive stamp and film may be removed.

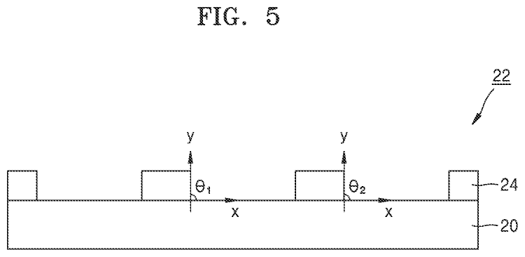

FIG. 5 is a cross-sectional view illustrating a plurality of grooves according to an embodiment.

Referring to FIG. 5, a structure of the plurality of grooves 23a, 23b, and 23c and the target molds 24 arranged spaced apart from each other in the target region 22 is illustrated.

One side surface of each of the plurality of grooves may be arranged to be inclined at an angle with respect to a surface of the target substrate 20. The angle may be predetermined.

The angle may mean an between one side of a partition wall of a target mold 24 and the planar surface of the target substrate 20. The angle between the surface of the target substrate 20 and the one side of the partition wall may be θ1 and θ2, which may be 80° to 90°.

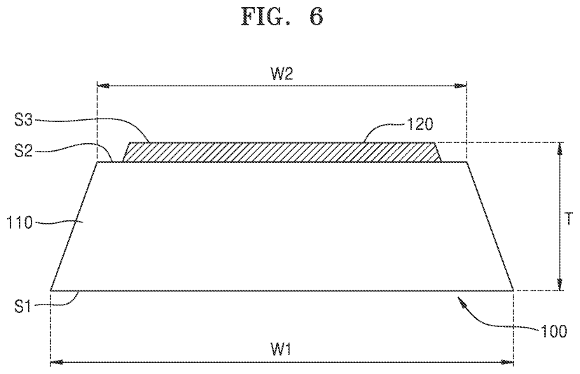

FIG. 6 is a diagram schematically illustrating a structure of an electronic chip according to an embodiment.

Referring to FIG. 6, the electronic chip 100 according to the embodiment may include a chip body 110 having a first surface S1 and a second surface S2 facing the first surface S1, and an electrode layer 120 arranged on the second surface S2 of the chip body 110.

The electronic chip 100 may be transferred to the target region of the target substrate by using the pick and place method according to an embodiment to repair the subpixels that require repair.

The electronic chips 100 may be configured to be easily aligned in one direction using a fluidic self-assembly method. Then, when aligning the plurality of electronic chips 100 on an external object such as a substrate by using a fluid self-assembly method, most or all of the plurality of electronic chips 100 may be aligned in the same direction. For example, the plurality of electronic chips 100 may be aligned so that the first surface S1 of the chip body 110 contacts an external object and an upper surface S3 of the electrode layer 120 does not contact the external object. The upper surface S3 of the electrode layer 120 is an opposite surface of the surface of the electrode layer 120 in contact with the second surface S2 of the chip body 110.

To this end, the electronic chip 100 may be configured so that the van der Waals force between the first surface S1 of the chip body 110 and the external object surface is greater than the van der Waals force between the upper surface S3 of the electrode layer 120 and the external object surface. In this case, the electronic chip 100 does not fall off relatively easily when the first surface S1 of the chip body 110 comes into contact with the external object surface, but the electronic chip 100 can fall off relatively easily when the upper surface S3 of the electrode layer 120 comes into contact with the external object surface. Therefore, when aligning the electronic chip 100, the probability that the electronic chip 100 is placed properly may increase so that the first surface S1 of the chip body 110 contacts the external object surface.

The van der Waals force may be greater as the two objects in contact with each other closely adhere to each other or as an area of contact between the two objects in contact with each other increases. Therefore, according to an embodiment, the surface roughness of the first surface S1 of the chip body 110 may be less than the surface roughness of the upper surface S3 of the electrode layer 120. For example, in some embodiments, the root mean square (rms) roughness of the first surface S1 of the chip body 110 may be about 1 nm or less, and the rms roughness of the upper surface S3 of the electrode layer 120 may be about 2 nm or more. In some embodiments, the rms roughness of the upper surface S3 of the electrode layer 120 may be twice or more times the rms roughness of the first surface S1 of the chip body 110. Here, the rms roughness of the first surface S1 of the chip body 110 is an average rms roughness of the entire region of the first surface S1, and may be different from the rms roughness in some local regions of the first surface S1 of the chip body 110. Similarly, the rms roughness of the upper surface S3 of the electrode layer 120 is an average rms roughness of the entire region of the upper surface S3 of the electrode layer 120, and may be different from the rms roughness in some local regions of the upper surface S3 of the electrode layer 120. As a result, a relatively very smooth surface is formed on the first surface S1, which is the lower part of the electronic chip 100, and a relatively uneven surface may be formed on the upper surface S3 of the electrode layer 120, which is the upper part of the electronic chip 100.

An area of the first surface S1 of the chip body 110 may be greater than an area of the second surface S2 of the chip body 110, and the area of the second surface S2 of the chip body 110 may be greater than an area of the upper surface S3 of the electrode layer 120. Accordingly, the area of the first surface S1 of the chip main body 110 may be greater than the area of the upper surface S3 of the electrode layer 120. To this end, the diameter or width W1 of the first surface S1 of the chip body 110 may be greater than a diameter or width W2 of the second surface S2 of the chip body 110. For example, the diameter or width W2 of the second surface S2 may be about 0.7 times or more but less than about 1 times or less, or about 0.8 times or more but about 0.95 times or less the diameter or width W1 of the first surface S1. Accordingly, the side surface of the electronic chip 100 may have an inclined shape.

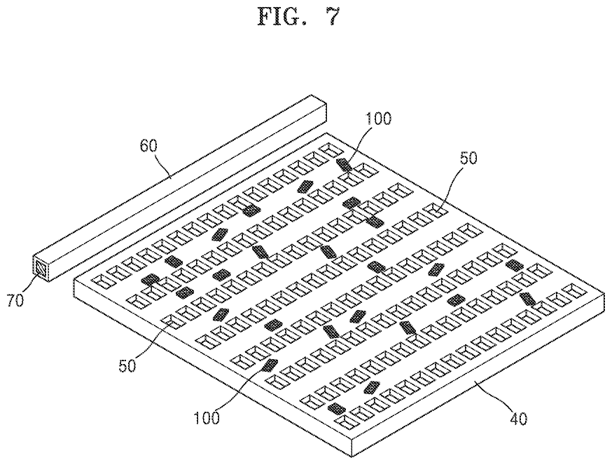

FIG. 7 is a perspective view illustrating a method of aligning a plurality of electronic chips using a fluid self-assembly method.

Referring to FIG. 7, the plurality of electronic chips 100 may be supplied on the upper surface of the transfer substrate 40 having a plurality of grooves 50 arranged in two dimensions on a surface of the transfer substrate 40 as illustrated in FIG. 7. After supplying liquid to the grooves 50 of the transfer substrate 40, the plurality of electronic chips 100 may be sprayed directly on the transfer substrate 40 or supplied onto the transfer substrate 40 in a state of being included in a suspension. Although the electronic chips 100 illustrated in FIG. 6 are illustrated in FIG. 7, the first electronic chips 100a, 100b, and 100c according to other embodiments may be used.

The liquid supplied to the grooves 50 may be any kind of liquid as long as the liquid does not corrode or damage the electronic chip 100. The liquid may be supplied to the grooves 50 in various ways, such as a spray method, a dispensing method, an inkjet dot method, and/or a method of flowing the liquid onto the transfer substrate 40. The liquid may include, for example, one of or a plurality of combination of the group including water, ethanol, alcohol, polyol, ketone, halocarbon, acetone, flux, and organic solvent. The organic solvent may include, for example, isopropyl alcohol (IPA). The supply amount of the liquid may be variously adjusted to fit the grooves 50 or to overflow into the grooves 50.

The plurality of electronic chips 100 may be sprayed directly onto the transfer substrate 40 without any other liquid or may be supplied onto the transfer substrate 40 in a state of being included in a suspension. Spray methods, dispensing methods that drop liquid, inkjet dot methods that discharge liquid like printing, and methods of flowing the suspension to the transfer substrate 40 may be used in various manners as a supply method of electronic chips 100 included in the suspension.

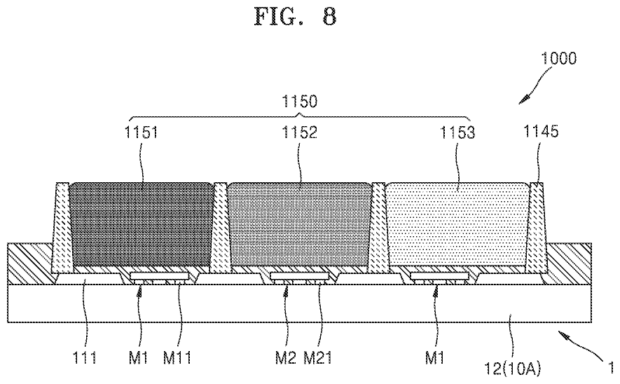

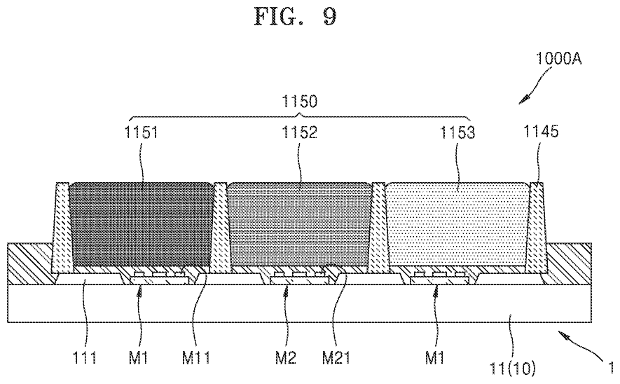

FIGS. 8 and 9 are cross-sectional views of a display device including a transfer device according to an embodiment.

Referring to FIGS. 8 and 9, the transfer device 1 according to an embodiment may be included in each of the display devices 1000 and 1000A. For example, each of the display devices 1000 and 1000A may include a transfer device 1 and a color conversion layer 1150 arranged on the transfer device 1. The transfer device 1 may include a substrate 10 with a base region 11.

The color conversion layer 1150 is provided between partition walls 1145. In some embodiments, an element may emit first color light, for example, blue light. However, the light emitted from the element is not limited thereto, and in some embodiments, the light emitted from the element may be light of other wavelengths that may excite the color conversion layer 1150.

The color conversion layer 1150 may include a first color conversion layer 1151 that converts or transmits light emitted from a first electronic chip M1 and a second electronic chip M2 into first color light, a second color conversion layer 1152 that converts light from the first and second electronic chips M1 and M2 into second color light, and a third color conversion layer 1153 that converts light from the first and second electronic chips M1 and M2 into third color light. The second color light may be green light, and the third color light may be red light.

When the first and second electronic chips M1 and M2 emit blue light according to some embodiments different from the plurality of second electronic chips 100a, 100b, and 100c described above, the first color conversion layer 1151 may include a resin that transmits blue light without light conversion. The second color conversion layer 1152 may convert blue light emitted from the first and second electronic chips M1 and M2 to emit green light. The second color conversion layer 1152 may include quantum dots (QDs) that are excited by blue light and emit green light, and the QDs may have a core-shell structure with a core and a shell, or a particle structure without a shell. The core-shell structure may be a single-shell structure or a multi-shell structure, such as a double-shell structure.

The QDs may include Group II-VI-based semiconductors, Group III-V-based semiconductors, Group IV-VI-based semiconductors, Group IV-based semiconductors, and/or graphene QDs. The QDs may include, for example, Cd, Se, Zn, S, and/or InP, and each QD may have a diameter of several tens of nm or less, for example, a diameter of about 10 nm or less.

The second color conversion layer 1152 may include phosphor that emits green light by being excited by blue light emitted from the first and second electronic chips M1 and M2.

The third color conversion layer 1153 may convert blue light emitted from the first and second electronic chips M1 and M2 into red light and emit the same. The third color conversion layer 1153 may include QDs of a predetermined size and emitting red light when excited by blue light, or phosphor that emits red light when excited by blue light emitted from the first and second electronic chips M1 and M2.

Each of the display devices 1000 and 1000A may emit red, green, and blue light through the color conversion layer 1150. In this case, the transfer device 1 may be applied to an RGB spontaneous light-emitting micro-LED TV. A display may be implemented by controlling the plurality of first and second electronic chips M1 and M2. In this way, the plurality of first and second electronic chips M1 and M2 transferred on the base substrate 10 may be electrically connected to perform one function.

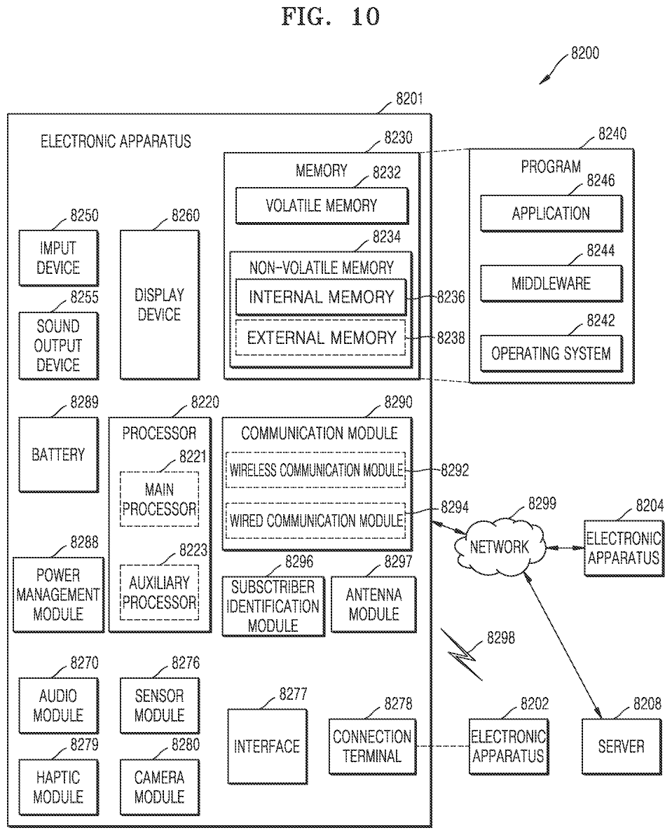

FIG. 10 is a block diagram of an electronic apparatus including a transfer device 1 according to an embodiment.

Referring to FIG. 10, an electronic apparatus 8201 may be provided in a network environment 8200. In the network environment 8200, an electronic apparatus 8201 may communicate with another electronic apparatus 8202 through a first network (short-range wireless communication network, etc.) 8298 or with another electronic apparatus 8204 and/or server (8208) through a second network (long-range wireless communication network, etc.) 8299. The electronic apparatus 8201 may communicate with the electronic apparatus 8204 through the server 8208. The electronic apparatus 8201 may include a processor 8220, a memory 8230, an input device 8250, an audio output device 8255, a display device 8260, an audio module 8270, a sensor module 8276, an interface 8277, a haptic module 8279, a camera module 8280, a power management module 8288, a battery 8289, a communication module 8290, a subscriber identification module 8296, and/or an antenna module 8297. Some of these components may be omitted from or other components may be added to the electronic apparatus 8201. Some of these components may be implemented in one integrated circuit. For example, the sensor module 8276 (fingerprint sensor, iris sensor, illuminance sensor, etc.) may be implemented by being embedded in the display device 8260 (display, etc.).

The processor 8220 may execute software (program 8240 or the like) to control one or a plurality of other components (hardware, software components, etc.) of the electronic apparatus 8201 connected to the processor 8220, and may perform various data processing or operations. As part of data processing or operation, the processor 8220 may load, in volatile memory 8232, commands and/or data received from other components (sensor modules 8276, communication modules 8290, etc.), process commands and/or data stored in the volatile memory 8232, and store the result data in nonvolatile memory 8234. The processor 8220 may include a main processor 8221 (a central processing unit, an application processor, etc.) and an auxiliary processor 8223 (a graphics processing unit, an image signal processor, a sensor hub processor, a communication processor, etc.) that may be operated independently of or together with the main processor 8221. The auxiliary processor 8223 may use less power than the main processor 8221 and perform a specialized function.

The auxiliary processor 8223 may control the functionality and/or status associated with some of the components of the electronic apparatus 8201 (the display device 8260, the sensor module 8276, the communication module 8290, etc.), in place of the main processor 8221 while the main processor 8221 is in an inactive state (sleep state), or in conjunction with the main processor 8221 while the main processor 8221 is in an active state (application execution state). The auxiliary processor 8223 (image signal processor, communication processor, etc.) may be implemented as part of other functionally related components (camera module 8280, communication module 8290, etc.).

The memory 8230 may store various data required by components (processor 8220 and sensor module 8276) of the electronic apparatus 8201. The data may include, for example, input data and/or output data for software (program 8240 or the like) and related commands. The memory 8230 may include a volatile memory 8232 and/or a nonvolatile memory 8234.

The program 8240 may be stored in the memory 8230 as software, and may include an operating system 8242, middleware 8244, and/or an application 8246.

The input device 8250 may receive commands and/or data to be used in components (processor 8220, etc.) of the electronic apparatus 8201 from the outside (user, etc.) of the electronic apparatus 8201. The input device 8250 may include a microphone, a mouse, a keyboard, and/or a digital pen (such as a stylus pen).

The sound output device 8255 may output the sound signal to the outside of the electronic apparatus 8201. The sound output device 8255 may include a speaker and/or a receiver. Speakers may be used for general purposes such as multimedia playback or recording playback, and receivers may be used to receive incoming calls. The receiver may be coupled as part of a speaker or may be implemented as an independent separate device.

The display device 8260 may visually provide information to the outside of the electronic apparatus 8201. The display device 8260 may include a display, a hologram device, or a projector and a control circuit for controlling the corresponding device. The display device 8260 may include the transfer device 1 described above. The display device 8260 may include a touch circuit configured to sense a touch, and/or a sensor circuit (a pressure sensor, etc.) configured to measure an intensity of a force generated by the touch.

The audio module 8270 may convert sound into an electrical signal or conversely convert the electrical signal into sound. The audio module 8270 may acquire sound through the input device 8250 or output sound through the sound output device 8255 and/or a speaker and/or a headphone of another electronic apparatus (e.g., electronic apparatus 8202, etc.) directly or wirelessly connected to the electronic apparatus 8201.

The sensor module 8276 may detect an operating state (power, temperature, etc.) or an external environmental state (user state, etc.) of the electronic apparatus 8201 and generate an electrical signal and/or a data value corresponding to the sensed state. The sensor module 8276 may include a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, and/or an illumination sensor.

The interface 8277 may support one or more designated protocols that may be used for electronic apparatus 8201 to be directly or wirelessly connected to another electronic apparatus (e.g., electronic apparatus 8202, etc.). The interface 8277 may include a high-definition multimedia interface (HDMI), a universal serial bus (USB) interface, an SD card interface, and/or an audio interface.

The connection terminal 8278 may include a connector through which the electronic apparatus 8201 may be physically connected to another electronic apparatus (e.g., electronic apparatus 8202, etc.). The connection terminal 8278 may include an HDMI connector, a USB connector, an SD card connector, and/or an audio connector (such as a headphone connector, etc.).

The haptic module 8279 may convert an electrical signal to a mechanical stimulus (vibration, motion, etc.) or an electrical stimulus that a user can recognize through a tactile or motion sensation. The haptic module 8279 may include a motor, a piezoelectric element, and/or an electrical stimulus device.

The camera module 8280 may capture a still image and a moving image. The camera module 8280 may include a lens assembly including one or more lenses, image sensors, image signal processors, and/or flashes. The lens assembly included in the camera module 8280 may collect light emitted from an object to be photographed.

The power management module 8288 may manage power supplied to the electronic apparatus 8201. The power management module 8288 may be implemented as part of a power management integrated circuit (PMIC).

The battery 8289 may supply power to components of the electronic apparatus 8201. The battery 8289 may include a non-rechargeable primary battery, a rechargeable secondary battery, and/or a fuel cell.

The communication module 8290 may establish a direct (wired) communication channel and/or wireless communication channel between the electronic apparatus 8201 and another electronic apparatus (the electronic apparatus 8202, the electronic apparatus 8204, the server 8208, etc.), and support communication execution through the established communication channel. The communication module 8290 may include one or more communication processors that operate independently of the processor 8220 (application processor, etc.) and support direct communication and/or wireless communication. The communication module 8290 may include a wireless communication module 8292 (a cellular communication module, a short-range wireless communication module, a GNSS (Global Navigation Satellite System, etc.) communication module, and/or a wired communication module 8294 (a local region network (LAN) communication module, a power line communication module, etc.). A corresponding communication module of these communication modules may communicate with other electronic apparatuses through a first network 8298 (a short-range communication network such as Bluetooth, WiFi Direct, or infrared data association (IrDA)), or a second network 8299 (a long-range communication network such as a cellular network, Internet, or computer network (LAN, WAN, etc.)). These various types of communication modules may be integrated into a single component (such as a single chip, etc.), or may be implemented as a plurality of separate components (multiple chips). The wireless communication module 8292 may identify and authenticate the electronic apparatus 8201 in a communication network such as a first network 8298 and/or a second network 8299 using subscriber information (such as an international mobile subscriber identifier (IMSI) stored in the subscriber identification module 8296.

The antenna module 8297 may transmit a signal and/or power to the outside (such as another electronic apparatus, etc.) or receive the signal and/or power from the outside. The antenna may include a radiator formed of a conductive pattern formed on the substrate (PCB, etc.). The antenna module 8297 may include one or a plurality of antennas. When a plurality of antennas are included, an antenna suitable for a communication scheme used in a communication network such as a first network 8298 and/or a second network 8299 may be selected from among the plurality of antennas by the communication module 8290. A signal and/or power may be transmitted or received between the communication module 8290 and another electronic apparatus through the selected antenna. Other components (RFIC, etc.) in addition to the antenna may be included as a part of the antenna module 8297.

Some of the components may be connected to each other via communication methods between peripherals (such as buses, General Purpose Input and Output (GPIO), Serial Peripheral Interface (SPI), and Mobile Industry Processor Interface (MIPI), etc.) to interchange signals (commands, data, etc.).

The command or data may be transmitted or received between the electronic apparatus 8201 and the external electronic apparatus 8204 through the server 8208 connected to the second network 8299. Other electronic apparatuses 8202 and 8204 may be the same or different types of apparatuses as the electronic apparatus 8201. All or some of the operations executed in the electronic apparatus 8201 may be executed in one or more of the other electronic apparatuses 8202, 8204, and 8208. For example, when the electronic apparatus 8201 needs to perform a function or service, it may request one or more other electronic apparatuses to perform part or all of the function or service instead of executing the function or service on its own. One or more other electronic apparatuses receiving the request may execute an additional function or service related to the request and transmit a result of the execution to the electronic apparatus 8201. To this end, cloud computing, distributed computing, and/or client-server computing technology may be used.

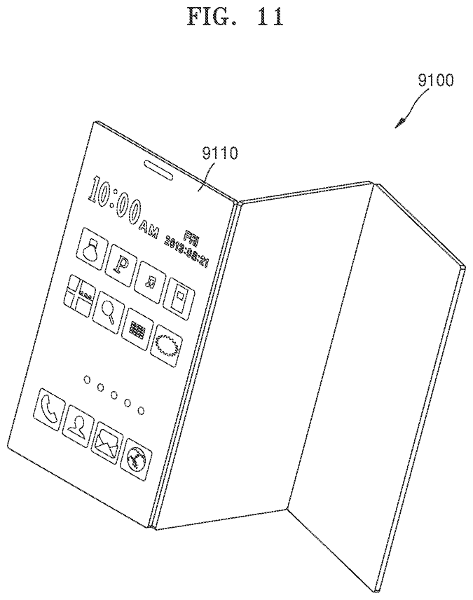

FIG. 11 illustrates an example of applying an electronic apparatus according to an embodiment to a mobile device 9100. The mobile device 9100 may include a display device 9110, according to an embodiment. The display device 9110 may include the transfer device 1 described above. The display device 9110 may have a foldable structure, for example, and may be a multi-foldable display. The mobile device 9100 is illustrated as a foldable display, but may also be a general flat panel display.

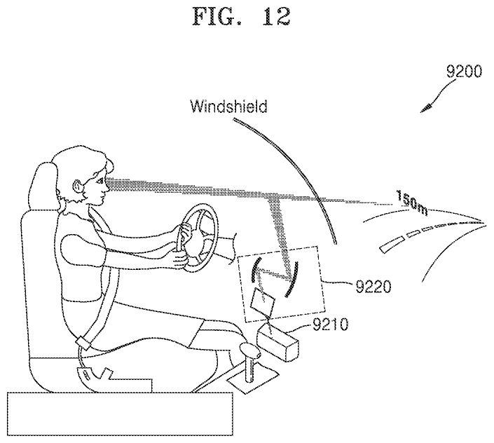

FIG. 12 illustrates an example of applying a display device according to an embodiment to a vehicle. The display device may be applied to a head-up display device for a vehicle. The head-up display device 9200 may include a display device 9210 in one region of the vehicle and at least one optical path change member 9220 that converts the path of light so that the driver may see images generated by the display device 9210.

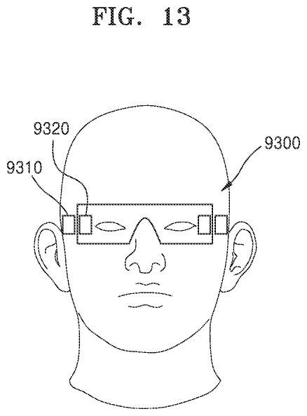

FIG. 13 illustrates an example of applying a display device according to an embodiment to augmented reality glasses or virtual reality glasses. The augmented reality glasses 9300 may include a projection system 9310 that forms an image and at least one element 9320 that guides the image from a projection system 9310 to enter the user's eyes. The projection system 9310 may include the transfer device 1 described above.

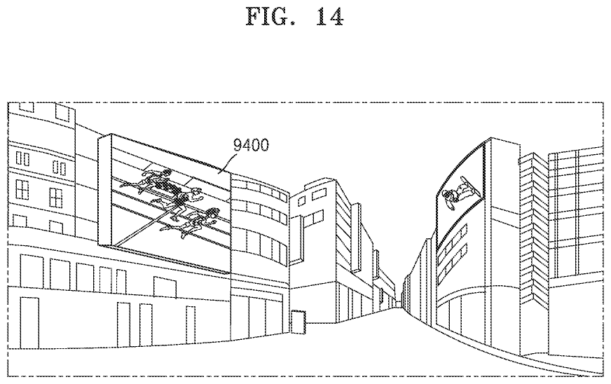

FIG. 14 illustrates an example of applying a display device according to an embodiment to a large signage. The signage 9400 may be used for outdoor advertisements using a digital information display, and may control advertisement content through a communication network. The signage 9400 may be implemented, for example, through the electronic apparatus described with reference to FIG. 10.

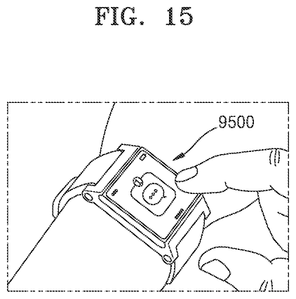

FIG. 15 illustrates an example of applying a display device according to an embodiment to a wearable display. The wearable display 9500 may include the transfer device 1 described above and may be implemented through the electronic apparatus described with reference to FIG. 10.

In the method of transferring a plurality of electronic chips according to the embodiments, the plurality of electronic chips may be separated from a base substrate by using a reusable relay substrate, and the separated electronic chips may be transferred to the target substrate. Since a predetermined adhesive between the electronic chips 100 and the base substrate 10 (or target substrate 20) is not used in the transferring of the plurality of electronic chips as described above, separation and transfer efficiency of the electronic chips may be improved. In other words, rather than using a predetermined adhesive between the electronic chips 100 and the base substrate 10 (or target substrate 20), a van der Waals force is used as described above.

The transfer method and transfer device for transferring the electronic chips according to the embodiments may improve the transfer yield of the electronic chips by repairing the electronic chips of the sub-pixel that needs repair on the substrate on which the electronic chips are transferred.

While various embodiments have been particularly shown and described with reference to the drawings, it will be understood that various changes in form and details may be made therein without departing from the spirit and scope of the following claims.

What is claimed is:

1. A method of transferring a plurality of electronic chips, the method comprising:
attaching, to a relay substrate, the plurality of electronic chips arranged on a base substrate;
separating the plurality of electronic chips from the base substrate;
wetting a target substrate using a solvent;
transferring, to the target substrate, the plurality of electronic chips that are attached to the relay substrate;
pressing the relay substrate in a thickness direction of the target substrate; and
drying the target substrate.

2. The method of claim 1, wherein a predetermined adhesive is not used to transfer the plurality of electronic chips from the relay substrate to the target substrate.

3. The method of claim 1, wherein, after the plurality of electronic chips are transferred to the target substrate, the relay substrate is reusable.

4. The method of claim 1, wherein the wetting comprises applying the solvent to a plurality of grooves provided in the target substrate.

5. The method of claim 4, wherein the solvent comprises at least one of H₂O, ethanol, acetone, and alcohol.

6. The method of claim 4, wherein the solvent does not chemically react with the plurality of electronic chips.

7. The method of claim 1, wherein the target substrate includes a first region in which a reference number of the plurality of electronic chips are arranged and a second region in which a number of the plurality of electronic chips that is less than the reference number are arranged, and
wherein the method further comprises:
removing all of the electronic chips in the second region from the second region, and
transferring the reference number of the electronic chips to the second region.

8. The method of claim 7, wherein the reference number of the electronic chips corresponds to sub-pixels of a display device.

9. The method of claim 7, wherein the transferring further comprises separating the reference number of the electronic chips from a base region provided on the base substrate on which the reference number of the electronic chips are arranged.

10. The method of claim 7, wherein the reference number of the electronic chips are transferred to the second region of the target substrate by a pick and place method.

11. The method of claim 7, wherein removing all of the electronic chips from the second region comprises separating all of the electronic chips included in the second region from the target substrate.

12. The method of claim 7, wherein the reference number of the electronic chips are transferred to a plurality of grooves in the target substrate.

13. The method of claim 1, wherein one side surface of each of the electronic chips is perpendicular to a surface of the target substrate.

14. The method of claim 4, wherein one side surface of each of the plurality of grooves is inclined at an angle with respect to a surface of the target substrate.

15. The method of claim 14, wherein the angle is 80° to 90°.

16. The method of claim 7, wherein transferring the reference number of the electronic chips to the second region comprises transferring the electronic chips so that the electronic chips are arranged in a same manner as the electronic chips are arranged on the base substrate from which the number of the electronic chips are transferred.

17. The method of claim 7, wherein transferring the reference number of the electronic chips to the second region comprises transferring the electronic chips such that electrodes included in the electronic chips face out from the target substrate.

18. The method of claim 7, wherein the target substrate comprises a plurality of grooves for accommodating each of the electronic chips.

19. The method of claim 1, wherein the target substrate comprises driving elements for a display device.

20. The method of claim 7, wherein:
the first region corresponds to a first sub-pixel for a display device, and
the second region corresponds to a second sub-pixel for the display device.

21. A transfer device comprising:
a target substrate having a plurality of grooves; and
a plurality of electronic chips transferred to the plurality of grooves by:
attaching, to a relay substrate, the plurality of electronic chips arranged on a base substrate;
separating the plurality of electronic chips from the base substrate;
wetting the target substrate using a solvent;
transferring, to the target substrate, the plurality of electronic chips that are attached to the relay substrate;
pressing the relay substrate in a thickness direction of the target substrate; and
drying the target substrate.
